(19) United States
(12) Patent Application Publication
(10) Pub. No.: US 2018/0112312 A1
(43) Pub. Date: Apr. 26, 2018

(54) FILM FORMING APPARATUS AND FILM FORMING METHOD

(71) Applicant: Tokyo Electron Limited, Tokyo (JP)

(72) Inventors: Masaya ODAGIRI, Yamanashi (JP); Hirotaka KUWADA, Yamanashi (JP); Hiroki EHARA, Yamanashi (JP); Yukihiro TAMEGAI, Yamanashi (JP); Tsuyoshi TAKAHASHI, Yamanashi (JP); Hideo NAKAMURA, Yamanashi (JP); Kazuyoshi YAMAZAKI, Yamanashi (JP); Yoshikazu IDENO, Yamanashi (JP)

(21) Appl. No.: 15/784,617

(22) Filed: Oct. 16, 2017

(30) Foreign Application Priority Data
Oct. 21, 2016 (JP) 2016-206730

(51) Int. Cl. C23C 16/455; C23C 16/30

(52) U.S. Cl. CPC C23C 16/45548; C23C 16/45574; C23C 16/303

(57) ABSTRACT

Disclosed is a film forming apparatus that forms a TiN film on a wafer by an ALD method. The film forming apparatus includes a chamber configured to accommodate the wafer, a gas supply mechanism configured to supply a titanium raw material gas including a TiCl₄ gas, a nitriding gas including a NH₃ gas, and a purge gas into the chamber, an exhaust mechanism configured to evacuate the inside of the chamber, and a controller configured to control the gas supply mechanism such that the TiCl₄ gas and the NH₃ gas are alternately supplied into the wafer. The gas supply mechanism has an NH₃ gas heating unit configured to heat the NH₃ gas to change a state of the NH₃ gas and supplies the NH₃ gas, the state of which is changed by the NH₃ gas heating unit, into the chamber.

### CROSS-REFERENCE TO RELATED APPLICATIONS

This application is based on and claims priority from Japanese Patent Application No. 2016-206730 filed on Oct. 21, 2016 with the Japan Patent Office, the disclosure of which is incorporated herein in its entirety by reference.

### TECHNICAL FIELD

The present disclosure relates to a film forming apparatus and a film forming method for forming a TiN film by an atomic layer deposition (ALD) method.

### BACKGROUND

On the manufacture of a semiconductor device, a TiN film is used for various applications such as a barrier film of a tungsten film and an electrode layer of a high dielectric film (high-k film).

In response to the recent miniaturization of devices, the ALD method, which is excellent in step coverage, has been used as a method of forming a TiN film. In the formation of the TiN film by the ALD method, a titanium tetrachloride (TiCl₄) gas, which is a raw material gas, and an ammonia (NH₃) gas, which is a nitriding gas, are alternately supplied, which is repeated a predetermined number of times to form a TiN film having a predetermined film thickness (see, e.g., Japanese Patent Laid-Open Publication No. 2015-214730).

Recently, an ultrathin film having a thickness of 2 to 3 nm or less is required as a TiN film. However, when the TiN film is formed by the ALD method using a TiCl₄ gas and an NH₃ gas, the concentration of chlorine in the film tends to increase as film thickness becomes thinner. This is probably because the ratio of the residual chlorine concentration to the film thickness becomes relatively higher as the film thickness becomes thinner. Due to the high ratio of the residual chlorine, the resistivity of the thin TiN film is larger than that of the thick TiN film, and in particular, the residual chlorine becomes a problem in the ultrathin film having a film thickness of 1.5 nm or less.

As a method of lowering the resistivity while lowering the chlorine concentration in the film and suppressing oxidation after film forming, there is a method of forming a film at a high temperature of 550 to 600° C. However, it is difficult to obtain a thin TiN film by this method because the film becomes thick until it becomes possible to obtain the film continuity when the film forming temperature is high. In order to obtain a thin TiN film, the film may be formed at a low temperature of 400 to 550° C.

In addition, it is possible to reduce the residual chlorine concentration by increasing the flow rate of NH₃ gas. However, it is difficult to obtain a sufficient residual chlorine concentration reduction effect because there is a limit to the flow rate that may be caused to flow depending on the capability of an exhaust pump.

### SUMMARY

A first aspect of the present disclosure provides a film forming apparatus which forms a TiN film on a processing target substrate by ALD method, the film forming apparatus including: a chamber configured to accommodate the processing target substrate; a gas supply mechanism configured to supply a titanium raw material gas including a titanium compound gas containing chlorine, a nitriding gas including a compound gas containing nitrogen and hydrogen, and a purge gas into the chamber; an exhaust mechanism configured to evacuate the inside of the chamber; and a controller configured to control the gas supply mechanism such that the titanium raw material gas and the nitriding gas are alternately supplied into the processing target substrate. The gas supply mechanism has a nitriding gas heating unit which heats the nitriding gas to change a state of the nitriding gas and supplies the state-changed nitriding gas by the nitriding gas heating unit, into the chamber.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating a film forming apparatus according to an exemplary embodiment of the present disclosure.

FIG. 2 is a view illustrating a gas supplying sequence of the film forming apparatus in FIG. 1.

FIG. 3 is a graph illustrating the relationship between the film thickness of a TiN film by XRF and the Cl concentration (CI 2p/Ti 2p) in the film by XPS when the removal of Cl in the film is not sufficiently performed.

FIG. 4 is a graph illustrating a thermal equilibrium of NH₃.

FIG. 5 is a graph illustrating the relationships between the flow rate of an NH₃ gas and resistivity when the NH₃ gas is heated and when the NH₃ gas is not heated.

FIG. 6 is a graph illustrating the relationships between the film thickness by XRF and the Cl concentration (Cl 2p/Ti 2p) in the film by XPS when the NH₃ gas is heated and when the NH₃ gas is not heated.

### DETAILED DESCRIPTION

In the following detailed description, reference is made to the accompanying drawings, which form a part thereof. The illustrative embodiments described in the detailed description, drawing, and claims are not meant to be limiting. Other embodiments may be utilized, and other changes may be made without departing from the spirit or scope of the subject matter presented here.

As described above, in a TiN film having a small film thickness, the concentration of chlorine in the film is increased and the resistivity is increased.

In addition, in a TiN film having a small film thickness, since there is a large amount of chlorine in the film, it is difficult to obtain a film having good continuity.

Therefore, the present disclosure provides a technology capable of obtaining a TiN film having a small amount of chlorine and a good TiN film thickness even when the film thickness is thin.

In order to solve the above-described problem, a first aspect of the present disclosure provides a film forming apparatus which forms a TiN film on a processing target substrate by an ALD method, the film forming apparatus including: a chamber configured to accommodate the processing target substrate; a gas supply mechanism configured to supply a titanium raw material gas including a titanium compound gas containing chlorine, a nitriding gas including a compound gas containing nitrogen and hydrogen, and a purge gas into the chamber; an exhaust mechanism configured to evacuate the inside of the chamber; and a controller configured to control the gas supply mechanism such that the titanium raw material gas and the nitriding gas are alternately supplied into the processing target substrate. The gas supply mechanism has a nitriding gas heating unit which heats the nitriding gas to change a state of the nitriding gas and supplies the nitriding gas, the state of which is changed by the nitriding gas heating unit, into the chamber.

In the film forming apparatus, a TiCl₄ gas may be properly used as the titanium raw material gas, and the NH₃gas may be properly used as the nitriding gas. The nitriding gas heating unit may heat the NH₃ gas to 100° C. or higher.

The nitriding gas heating unit has a curved flow path therein and a heater embedded therein. By heating the heater to a predetermined set temperature, it is possible to heat the nitriding gas flowing through the flow path by heat exchange.

The gas supply mechanism includes: a Ti raw material gas source configured to supply the Ti raw material gas; a nitriding gas source configured to supply the nitriding gas; a first purge gas source and a second purge gas source configured to supply the purge gas; a first gas supply pipe connected to the Ti raw material gas source and configured to supply the Ti raw material gas into the chamber; a second gas supply pipe connected to the nitriding gas supply source and configured to supply the nitriding gas into the chamber; a third gas supply pipe connected to the first purge gas source and joining the first gas supply pipe; a fourth gas supply pipe connected to the second purge gas source and joining the second gas supply pipe; and an open/close valve provided in each of the first to fourth gas supply pipes. The nitriding gas heating unit is provided on a downstream side of a portion in which the fourth gas supply pipe of the second gas supply pipe joins. The controller opens the open/close valves of the third gas supply valve and the fourth gas supply pipe, during film formation so as to cause the purge gas to constantly flow, and intermittently and alternately open/close the open/close valves of the first gas supply pipe and the second gas supply pipe. The purge gas is constantly supplied to the nitriding gas heating unit and heated, and the nitriding gas is intermittently supplied together with the purge gas such that the nitriding gas is heated together with the purge gas.

A heating mechanism configured to heat the processing target substrate may be further provided with the film forming apparatus, and the controller may control the heating mechanism such that a temperature of the processing target substrate reaches a temperature within 400 to 550° C.

A second aspect of the present disclosure provides a film forming method including intermittently and alternately supplying a titanium raw material gas including a titanium compound gas containing chlorine and a nitriding gas including a compound gas containing nitrogen and hydrogen into a chamber in which a processing target substrate is accommodated and held under a reduced pressure; and forming a TiN film on the processing target substrate by an ALD method. The film forming method further includes heating the nitriding gas to change a state of the nitriding gas and supplying the state-changed nitriding gas into the chamber.

In the film forming method, a TiCl₄ gas may be properly used as the titanium raw material gas, and the NH₃ gas may be properly used as the nitriding gas. The NH₃ gas, which is nitriding gas, may be heated to 100° C. or higher.

A purge gas may be supplied into the chamber between the supplying the titanium raw material gas and the supplying the nitriding gas so as to purge the inside of the chamber. In this case, the purge gas may be constantly supplied into the chamber during film formation, the Ti raw material gas and the nitriding gas are intermittently and alternately supplied together with the purge gas, the purge gas may be constantly heated in a pipe in which the nitriding gas and the purge gas join, and the nitriding gas may be heated together with the purge gas when the nitriding gas is supplied.

A temperature of the processing target substrate may be controlled to a temperature within a range of 400 to 550° C.

A third aspect of the present disclosure provides a non-transitory computer-readable storage medium which stores a computer that when executed, causes the computer to control the film forming apparatus so that the film forming method of the second aspect is performed.

According to the present disclosure, a titanium raw material gas including a titanium compound gas containing chlorine and a nitriding gas including a compound gas containing nitrogen and hydrogen are intermittently and alternately supplied into the chamber which accommodates the processing target substrate so as to form a TiN film by an ALD method so that the nitriding gas is heated to change the state of the nitriding gas. Further, since the state-changed nitriding gas is supplied into the chamber, the reactivity between the nitriding gas and chlorine in the film may be increased, and even when the film thickness is thin, a good TiN film having a small amount of chlorine may be obtained.

Hereinafter, exemplary embodiments of the present disclosure will be described with reference to the accompanying drawings.

### Example of Film Forming Apparatus

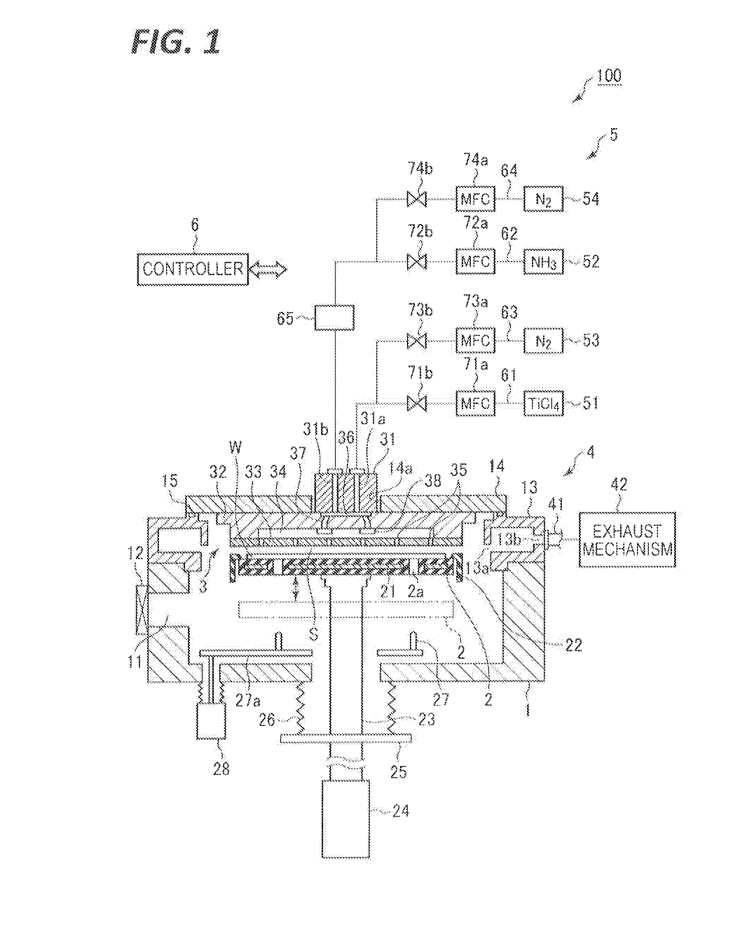

FIG. 1 is a cross-sectional view illustrating a film forming apparatus according to an exemplary embodiment of the present disclosure.

The film forming apparatus 100 forms a TiN film by an ALD method using a TiCl₄ gas as a raw material gas and an NH₃ gas as a nitriding gas, and includes a chamber 1, is susceptor 2 configured to horizontally support, in the chamber 1, a semiconductor wafer (hereinafter, simply referred to as a “wafer”) W which is a processing target substrate, a gas introduction portion 3 configured to introduce a processing gas into the chamber 1, an exhaust portion 4 configured to evacuate the inside of the chamber 1, a processing gas supply mechanism 5 configured to supply the processing gas to the gas introduction portion 3, and a controller 6.

The chamber 1 is made of a metal such as, for example, aluminum and has a substantially cylindrical shape. A carry-in/out port 11 configured to carry into/out the wafer W is formed in the sidewall of the chamber 1, and the carry-in/out port 11 is configured to be opened/closed by a gate valve 12. An annular exhaust duct 13 having a rectangular cross section is provided above the main body of the chamber 1. A slit 13a is formed in the exhaust duct 13 along the inner circumferential surface. Further, an exhaust port 13b is formed in the outer wall of the exhaust duct 13. A top wall 14 is provided on the upper surface of the exhaust duct 13. An opening 14a configured to insert a gas introduction block (to be described later) thereinto is formed in the center of the top wall 14, and a space between the top wall 14 and the exhaust duct 13 is airtightly sealed by a seal ring 15.

The susceptor 2 has a disc shape having a size corresponding to the wafer W, and is supported by a support member 23. The susceptor is made of a ceramic material such as, for example, aluminum nitride (AIN) or a metal material such as, for example, an aluminum or nickel-based alloy, and a heater 21 configured to heat the wafer W is embedded in the susceptor 2. The heater 21 is supplied with electric power from a heater power source (not illustrated) to generate heat. Then, the wafer W is controlled to a predetermined temperature by controlling the output of the heater 21 by a temperature signal of a thermocouple (not illustrated) provided in the vicinity of a wafer mounting surface on the upper surface of the susceptor 2.

The susceptor 2 is provided with a cover member 22 made of ceramics such as, for example, alumina to cover the outer peripheral region of the wafer mounting surface and the side surface of the susceptor 2.

The support member 23 supporting the susceptor 2 extends from the center of the bottom surface of the susceptor 2 to the lower side of the chamber 1 through a hole formed in the bottom wall of the chamber 1 and the lower end of the support member 23 is connected to a lifting mechanism 24. The lifting mechanism 24 allows the susceptor 2 to move up and down between a processing position illustrated in FIG. 1 and a conveying position at which the wafer illustrated by the lower dash line may be conveyed, via the support member 23. A flange unit 25 is attached to a portion of the support member 23, which is below the chamber 1. Between the bottom surface of the chamber 1 and the flange unit 25, there is provided a bellows 26 that separates the atmosphere in the chamber 1 from outside air and expands and contracts with the ascending and descending operation of the susceptor 2.

In the vicinity of the bottom surface of the chamber 1, three (only two illustrated) wafer support pins 27 are provided so as to protrude upward from a lifting plate 27a. The water support pins 27 may be moved up and down via a lifting plate 27a by a pin lifting mechanism 28 provided below the chamber 1, and are inserted into a through hole 2a provided in the susceptor 2 at the conveying position and may be projected with respect to the upper surface of the susceptor 2. By moving the wafer support pins 27 up and down, the wafer W is conveyed between a wafer conveying mechanism (not illustrated) and the susceptor 2.

The gas introduction portion 3 is provided to face the susceptor 2 and includes a gas introduction block 31 inserted into an opening 14a in the center of the top wall 14, a main body portion 32 which supports the gas introduction block 31 and has a disk shape that is in close contact with the lower surface of the top wall 14, and a shower plate 33 connected to the lower portion of the main body portion 32. A gas diffusion space 34 is formed between the main body portion 32 and the shower plate 33. A plurality of gas discharge holes 35 are formed on the lower surface of the shower plate 33. In a state where the susceptor 2 is at the processing position, a processing space S is formed between the shower plate 33 and the susceptor 2.

The gas introduction block 31 is formed with a first gas introduction hole 31a and a second gas introduction hole 31b. The first gas introduction hole 31a and the second gas introduction hole 31b are connected to a gas diffusion portion 36 on the upper surface of the main body portion 32. A plurality of gas supply passages 37 extend downward from the gas diffusion portion 36, and a gas discharge member 38 having a plurality of discharge ports is connected to the front end of the gas supply passage 37 to face a gas diffusion space 34.

The exhaust portion 4 includes an exhaust pipe 41 connected to the exhaust port 13b of the exhaust duct 13 and an exhaust mechanism 42 connected to the exhaust pipe 41 and having a vacuum pump, a pressure control valve, or the like. During the processing, the gas in the chamber 1 reaches the exhaust duct 13 via the slit 13a and is exhausted from the exhaust duct 13 through the exhaust pipe 41 by the exhaust mechanism 42 of the exhaust portion 4.

The processing gas supply mechanism 5 includes: a TiCl₄ gas source 51 configured to supply TiCl₄ gas which is a Ti raw material gas; an NH₃ gas source 52 configured to supply NH₃ gas which is a nitriding gas; a first N₂ gas source 53 and a second N₂ gas source 54 configured to supply N₂ gas which is a purge gas; a first gas supply pipe 61 extending from the TiCl₄ gas source 51; a second gas supply pipe 62 extending from the NH₃ gas source 52; a third gas supply pipe 63 extending from the first N₂ gas source 53; a fourth gas supply pipe 64 extending from the second N₂ gas source 54; and an NH₃ gas heating unit 65.

The first gas supply pipe 61 is connected to the first gas introduction hole 31a of the gas introduction block 31, and the second gas supply pipe 62 is connected to the second gas introduction hole 31b of the gas introduction block 31 through the NH₃ gas heating unit 65. The third gas supply pipe 63 is connected by the first gas supply pipe 61. The fourth gas supply pipe 64 is connected by the second gas supply pipe 62.

The first gas supply pipe 61 is provided with a mass flow controller 71a and an open/close valve 71b which are flow rate controllers, the second gas supply pipe 62 is provided with a mass flow controller 72a and an open/close valve 72b, the third gas supply pipe 63 is provided with a mass flow controller 73a and an open/close valve 73b, and the fourth gas supply pipe 64 is provided with a mass flow controller 74a and an open/close valve 74b.

The gas introduced into the first gas introduction hole 31a and the second gas introduction hole 31b is diffused into the gas diffusion space 34 via the gas diffusion portion 36 the gas supply passage 37, and the gas discharge member 38, discharged from the gas discharge holes 35 of the shower plate 33 to the processing space S, and supplied to the wafer W.

During an ALD process, the open/close valves 73b and 74b are normally opened to cause the N₂ gas, which is a purge gas, to constantly flow, and the TiCl₄ gas and the NH₃ gas are alternately supplied into the chamber 1 while the purging of the chamber is performed between the supply of the TiCl₄ gas and the supply the NH₃ gas by intermittently and alternately opening/closing the open/close valves 71b and 72b. The formation of the TiN film by the ALD method is performed as described later.

The NH₃ gas heating unit 65 is provided on the downstream side of a portion where the fourth gas supply pipe 64 of the second gas supply pipe 62 joins. Accordingly, during the ALD process, the N₂ gas, which is a purge gas, is continuously supplied to the NH₃ gas heating unit 65 and is heated, and the NH₃ gas is intermittently supplied thereto.

The NH₃ gas heating unit 65 has a curved gas flow path therein and also has a heater embedded therein. By heating the heater to a predetermined set temperature, the NH₃ gas flowing in the gas flow path together with the N₂ gas is heated by heat exchange.

The controller 6 includes respective components, specifically, mass flow controllers 71a, 72a, 73a, and 74a, open/close valves 71b, 72b, 73b, and 74b, an NH₃ gas heating unit 65, a main controller having a central processing unit (CPU) configured to control, for example, the power source of the heater 21, a lifting mechanism 24, a pin lifting mechanism 28, and an exhaust mechanisms 42, an input device, an output device, a display device, and a storage device. The storage device stores parameters of various processes executed in the film forming apparatus 100 and sets a storage medium in which a program configured to control processes executed in the film forming apparatus 100, that is, a process recipe is stored. The main controller calls the predetermined process recipe stored in the storage medium and controls the film forming apparatus 100 to execute the predetermined process based on the process recipe.

In the film forming apparatus 100 configured as described above, the gate valve 12 is first opened and the wafer W is carried into the chamber 1 through the carry-in/out port 11 by a conveying device (not illustrated), the wafer W is placed on the susceptor 2, and the conveying device is retracted so as to raise the susceptor 2 to the processing position. Then, the gate valve 12 is closed to keep the inside of the chamber 1 at a predetermined decompressed state and the temperature of the susceptor 2 is controlled to a predetermined temperature of 400 to 550° C. by the heater 21.

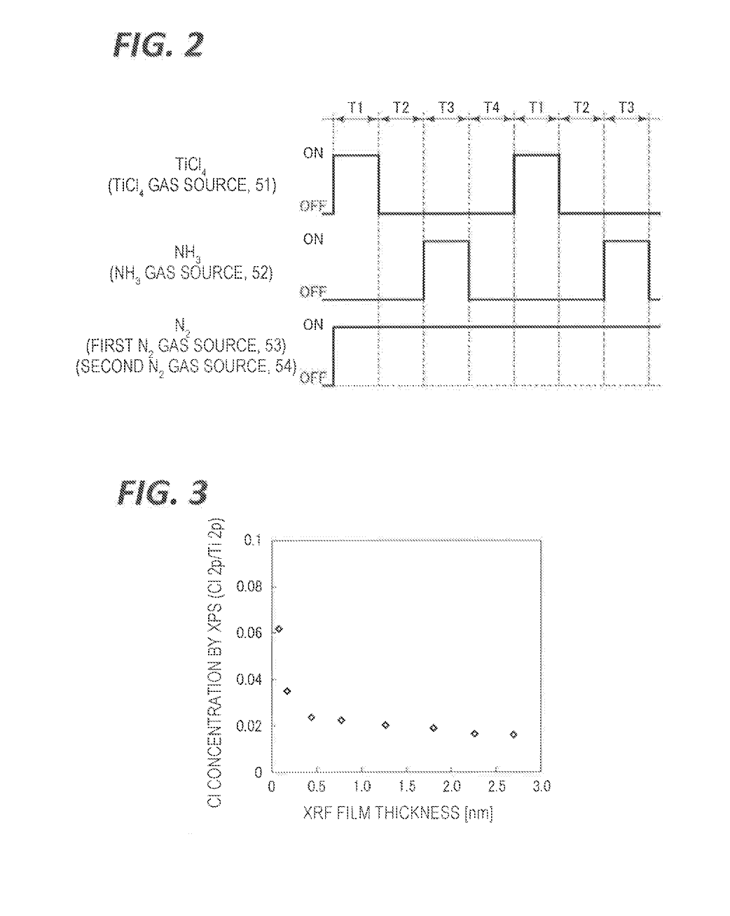

In this state, the N₂ gas, which is a purge gas, is continuously supplied to the processing space S from the first N₂ gas source 53 and the second N₂ gas source 54 through the shower plate 33 of the gas introduction portion 3. By alternately intermittently opening and closing the open/close valve 71b of the first gas supply pipe 61 and the open/close valve 72b of the second gas supply pipe 62 while continuing the supply of the N₂ gas, the TiCl₄ gas and the NH₃ gas are intermittently and alternately supplied to the processing space S. As illustrated in FIG. 2, the supply period T1 of the N₂ gas and the TiCl₄ gas, the supply period T2 of the N₂ gas only, the supply period T3 of the N₂ gas and the gas, and the supply period T4 of the N₂ gas only are sequentially performed and these steps are repeated. That is, the supplying of the TiCl₄ gas, the purging in the chamber, the supplying of the NH₃ gas, and the purging to the chamber are set to one cycle, and these steps are repeated to form the TiN film on the wafer W by a thermal ALD.

In this case, the TiCl₄ gas supplied in the supply period T1 is absorbed on the substrate (e.g., Si) and reacts with the NH₃ gas supplied in the supply period T3 after the supply period T2. As a result, HCl is generated so that chlorine (Cl) is removed and TiN is generated. When Cl is not sufficiently removed at this time, the concentration of residual chlorine in the TiN film to be formed is increased and the resistivity of the film is increased. In particular, as the film thickness becomes thinner, the residual Cl concentration tends to becomes higher. FIG. 3 illustrates a relationship between the film thickness of the TiN film by XRF and the Cl concentration (Cl 2p/Ti 2p) in the film by XPS. However, as the film thickness becomes thinner, the Cl concentration in the film becomes higher. Especially, when the film thickness is less than 0.5 nm, the Cl concentration in the film suddenly becomes higher.

The Cl concentration in the film may be reduced by setting the film forming temperature to a high temperature of 550 to 600° C. However, it is difficult to obtain a thin TiN film by this method because the film becomes thick until the film continuity may be obtained when the film forming temperature is high. In order to obtain a thin TiN film, the film has to be formed at a low temperature of 400 to 550° C. In addition, it is possible to reduce the residual chlorine concentration by increasing the flow rate of the NH₃ gas. However, it is difficult to obtain a sufficient residual chlorine concentration reduction effect because there is a limit to the flow rate that may be caused to flow depending on the capability of an exhaust pump.

Further, when residual Cl exists in the film forming process, since there is an electrically repulsive force between the residual Cl and TiCl₄, it is sometimes difficult to sufficiently increase the film continuity in the thin film of the TiN film.

Therefore, in this exemplary embodiment, in order to form a thin film of the TiN film without causing the above-described problem, the NH₃ gas heating unit 65 is provided in the NH₃ gas supply passage to heat the NH₃ gas, to improve the reactivity of the NH₃gas with the residual Cl, and to accelerate the release of Cl from the film.

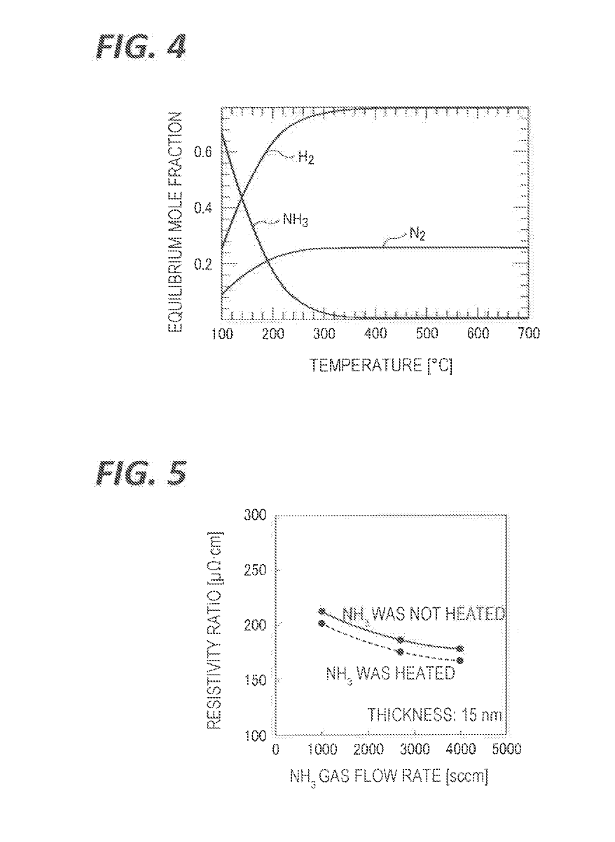

In an ammonia decomposition method, which is one of the technologies for producing hydrogen from a fuel cell, NH₃ is decomposed (dissociated) at a high temperature using a thermal equilibrium state as illustrated in FIG. 4 (refer to a technical report by Reaction Design Inc., “Hydrogen Production Reaction by Ammonia Decomposition Method,” 2012). As illustrated in FIG. 4, the decomposition of NH₃ tends to be accelerated at a higher temperature, and most of NH₃ decomposes at a temperature above 400° C. In this exemplary embodiment, using this phenomenon, the NH₃ gas is heated to form a highly reactive state in which at least a portion of NH₃ is dissociated, thereby accelerating the reaction of removing Cl. When the NH₃ gas is introduced into the chamber 1, the temperature drops near room temperature, but the state of high reactivity with Cl is maintained.

As a result, it is possible to exhibit a high Cl removal effect without setting the film forming temperature to a high temperature and increasing the flow rate of the NH₃ gas, and it is possible to lower the Cl concentration in the film even with the thin TiN film. For this reason, the resistivity of the TiN film may be reduced. It is also possible to make the flow rate of the NH₃ gas to obtain equivalent resistivity smaller than that in the related art.

Further, by more properly controlling the heating condition of the NH₃ gas, the Cl concentration in the film may be lowered and the film continuity may be improved. Thus, further improvement of the characteristics such as the reduction of leakage current is expected.

As illustrated in FIG. 4, since the NH₃ gas is decomposed by about 40% even at 100° C., the heating temperature of the gas may be 100° C. or higher. From the viewpoint that the decomposition ratio is 50% or more, the heating temperature of the NH₃ gas may be 120° C. or higher, 150° C. or higher, or 200° C. or higher.

In this exemplary embodiment, the NH₃ gas heating unit 65 is provided at the downstream side of a portion where the fourth gas supply pipe 64 of the second gas supply pipe 62 joins. During the ALD process, the NH₃ gas heating unit is continuously supplied with the N₂ gas, which is a purge gas, and is heated, and the NH₃ gas is intermittently supplied with the N₂ gas and the NH₃ gas is heated with the N₂ gas. Therefore, the temperature stability the NH₃ gas may be maintained high.

Also, in this exemplary embodiment, the NH₃ gas heating unit 65 has a curved gas flow path therein and also has a heater embedded therein. The NH₃ gas heating unit has a structure in which, by heating the heater to a predetermined set temperature, the NH₃ gas flowing in the gas flow path together with the N₂ gas is heated by heat exchange. With this structure, the NH₃ gas at a predetermined flow rate may be efficiently heated to a predetermined temperature.

In fact, the chlorine concentration in the film and the resistivity of the film were compared between when the NH₃ gas was heated and when the NH₃ gas was not heated. By setting the film forming temperature (wafer temperature) to 400 to 550° C., the flow rate of TiCl₄ gas to 20 to 150 sccm (ml/min), the flow rate (total) of N₂ gas to 7000 to 20000 sccm (mL/min), and the pressure to 2 to 10 Torr (267 to 1333 Pa), and varying the flow rate of NH₃ gas to 1000 sccm (mL/min), 2500 sccm (mL/min), and 4000 sccm (mL/min), the resistivity of the film when the film thickness was 15 nm was measured. At this time, the set temperature of the NH₃ gas heating unit was set to 400° C. The actual temperature of the gas immediately after the NH₃ gas heating unit is about 200° C. It is considered that the heating temperature in the NH₃ gas heating unit is about 400° C.

FIG. 5 is a graph illustrating the relationship between the flow rate of the NH₃ gas and resistivity when the NH₃ gas is heated and when the NH₃ gas is not heated. As illustrated in this figure, it was confirmed that the resistivity is reduced by 5 to 6% by heating the NH₃ gas at any flow rate.

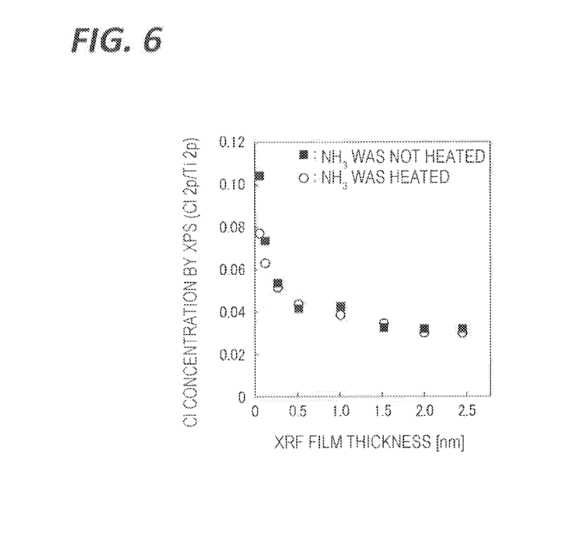

Next, the relationship between the film thickness by XRF and the Cl concentration (Cl 2p/Ti 2p) in the film by XPS was confirmed when the NH₃ gas is heated and when the NH₃ gas is not heated. The flow rate of the NH₃ gas was set to 4000 sccm (mL/min) at this time. The result is illustrated in FIG. 6. As illustrated in FIG. 6, it was confirmed that, with the heating of the NH₃ gas, the Cl concentration was reduced by as much as 30% in an ultrathin film having a thickness of about 0.1 nm.

Further, in the heating of the NH₃ gas under the above-described conditions, although the film continuity did not exhibit a clear difference from that in the case where the heating was not performed, but film continuity is expected to be improved by further increasing the heating temperature of the NH₃ gas.

The preferred ranges of the processing conditions other than the temperature of heating the NH₃ gas when forming the TiN film in this exemplary embodiment are as follows.

Pressure: 2 to 10 Torr (267 to 1333 Pa)

Film forming temperature (wafer temperature): 400 to 550° C.

TiCl₄ gas flow rate: 20 to 150 sccm (mL/min)

NH₃ gas flow rate: 1000 to 10000 sccm (mL/min)

N₂ gas flow rate (total): 7000 to 20000 sccm (mL/min)

Time T1 (per one time): 0.01 to 1.0 sec

Time T3 (per one time): 0.1 to 1.0 sec

Time T2 (purging) (per one time): 0.1 to 1.0 sec

Time T4 (purging) (per one time): 0.1 to 1.0 sec

After the TiN film is formed by the ALD method as described above, the inside of the chamber 1 is purged, the susceptor 2 is lowered, the gate valve 12 is opened, and the wafer W is carried out.

### Other Applications

Exemplary embodiments of the present disclosure have been described above, but the present disclosure is not limited to the above-described exemplary embodiments and various modifications may be made within the scope of the spirit of the present disclosure. For example, TiCl₄ was used as a Ti raw material gas in the above-described exemplary embodiment, but another raw material gas may be applied as long as it is a Ti compound containing Cl. Further, an NH₃ gas was used as a nitriding gas, but another nitriding gas may be applied as long as it is a compound containing N and H. In addition, in the above-described exemplary embodiment, an N₂ gas was used as a purge gas, but other inert gas such as, for example, an Ar gas may be used.

Further, in the above-described exemplary embodiment, the NH₃ gas heating unit has a curved gas flow path therein and also includes a heater embedded therein. The NH₃ gas heating unit has a structure in which, by heating the heater to a predetermined set temperature, the NH₃ gas flowing in the gas flow path together with the N₂ gas is heated by heat exchange. However, the present disclosure is not limited to this structure.

Further, although the semiconductor wafer has been described as an example of a processing target substrate in the above-described exemplary embodiment, the semiconductor wafer may be silicon or a compound semiconductor such as GaAs, SiC, or GaN. Also, the present disclosure is not limited to the semiconductor wafer, but may be applied to, for example, a glass substrate or a ceramic substrate used for a flat panel display (FPD) such as a liquid crystal display device.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A film forming apparatus that forms a TiN film on a processing target substrate by an ALD method, the film forming apparatus comprising:
a chamber configured to accommodate the processing target substrate therein;
a gas supply mechanism configured to supply a titanium (Ti) raw material gas including a titanium compound gas containing chlorine, a nitriding gas including a compound gas containing nitrogen and hydrogen, and a purge gas into the chamber;
an exhaust mechanism configured to evacuate an inside of the chamber; and
a controller configured to control the gas supply mechanism such that the titanium raw material gas and the nitriding gas are alternately supplied into the processing target substrate,
wherein the gas supply mechanism has a nitriding gas heating unit configured to heat the nitriding gas so as to change a state of the nitriding gas and supplies the nitriding gas, the state of which is changed by the nitriding gas heating unit, into the chamber.

2. The film forming apparatus of claim 1, wherein the titanium raw material gas is a TiCl₄ gas.

3. The film forming apparatus of claim 1, wherein the nitriding gas is an NH₃ gas.

4. The film forming apparatus of claim 3, wherein the nitriding gas heating unit heats the gas to NH₃ gas to 100° C. or higher.

5. The film forming apparatus of claim 1, wherein the nitriding gas heating unit includes a curved gas flow path therein and a heater embedded therein and heats the nitriding gas flowing through the gas flow path by heat exchange by heating the heater to a predetermined set temperature.

6. The film forming apparatus of claim 1, wherein the gas supply mechanism includes:
a Ti raw material gas source configured to supply the Ti raw material gas;
a nitriding gas source configured to supply the nitriding gas;
a first purge gas source and a second purge gas source configured to supply the purge gas;
a first gas supply pipe connected to the Ti raw material gas source and configured to supply the Ti raw material gas into the chamber;
a second gas supply pipe connected to the nitriding gas supply source and configured to supply the nitriding gas into the chamber;
a third gas supply pipe connected to the first purge gas source and joining the first gas supply pipe;
a fourth gas supply pipe connected to the second purge gas sourer and joining the second gas supply pipe; and
an open/close valve provided in each of the first to fourth gas supply pipes,
the nitriding gas heating unit is provided on a downstream side of portion in which the fourth gas supply pipe of the second gas supply pipe joins,
the controller opens the open/close valves of the third gas supply pipe and the fourth gas supply pipe, during film formation so as to cause the purge gas to constantly flow, and intermittently and alternately open/close the open/close valves of the first gas supply pipe and the second gas supply pipe, and
the purge gas is constantly supplied to the nitriding gas heating unit and heated, and the nitriding gas is intermittently supplied together with the purge gas such that the nitriding gas is heated together with the purge gas.

7. The film forming apparatus of claim 1, further comprising:
a heating mechanism configured to heat the processing target substrate,
wherein the controller controls the heating mechanism such that a temperature of the processing target substrate reaches a temperature within a range of 400 to 550° C.

8. A film forming method comprising:
intermittently and alternately supplying a titanium (Ti) raw material gas including a titanium compound gas containing chlorine and a nitriding gas including a compound gas containing nitrogen and hydrogen into a chamber in which a processing target substrate is accommodated and held under a reduced pressure; and
forming TiN film on a processing target substrate by an ALD method,
wherein in the film forming method, the nitriding gas is heated to change a state of the nitriding gas and state-changed nitriding gas is supplied into the chamber.

9. The film forming method of claim 8, wherein the titanium raw material gas is a TiCl₄ gas.

10. The film forming method of claim 8, wherein the nitriding gas is an NH₃ gas.

11. The film forming method of claim 10, wherein the NH₃ gas is heated to 100° C. or higher.

12. The film forming method of claim 8, wherein a purge gas is supplied into the chamber between the supplying the titanium raw material gas and the supplying the nitriding gas so as to purge an inside of the chamber.

13. The film forming method of claim 12, further comprising:
constantly supplying the purge gas into the chamber during film formation,
wherein the Ti raw material gas and the nitriding gas are supplied together with the purge gas intermittently and alternately; the purge gas is constantly heated in a pipe in which the nitriding gas and the purge gas join; and the nitriding gas is heated together with the purge gas when the nitriding gas is supplied.

14. The film forming method of claim 8, wherein a temperature of the processing target substrate is controlled to a temperature within a range of 400 to 550° C.

15. A non-transitory computer-readable storage medium which stores a program that when executed, causes the computer to control a film forming apparatus to perform the film forming method of claim 8.
